(19) United States
(12) Patent Application Publication
(10) Pub. No.: US 2026/0091506 A1
(43) Pub. Date: Apr. 2, 2026

(54) TRANSPORT ROBOT

(71) Applicant: NIDEC INSTRUMENTS CORPORATION, Nagano (JP)

(72) Inventor: Takao NAKAE, Nagano (JP)

(73) Assignee: NIDEC INSTRUMENTS CORPORATION, Nagano (JP)

(21) Appl. No.: 19/340,747

(22) Filed: Sep. 25, 2025

(30) Foreign Application Priority Data
Sep. 30, 2024 (JP) 2024-171049

(51) Int. Cl. B25J 11/00; H01L 21/677; H01L 21/687

(52) U.S. Cl. CPC B25J 11/0095; H10P 72/3402; H10P 72/7602

(57) ABSTRACT

To provide a transport robot 1 including a first hand including a chuck mechanism to clamp and hold an outer peripheral end portion of a workpiece, and a first movement mechanism to move the first hand to an advancing position where the workpiece contained in the cassette case can be held and to a retreating position farther from a cassette case than the advancing position, in which when a direction connecting the retreating position and the advancing position is defined as an X direction, a direction from the retreating position toward the advancing position is defined as an X1 direction, and a direction from the advancing position toward the retreating position is defined as an X2 direction, a chuck mechanism includes a chuck portion openable and closable vertically, and a movement mechanism to move the chuck portion into the X direction.

### CROSS-REFERENCE TO RELATED APPLICATION

This application claims the benefit of JP Patent Application No. 2024-171049, filed on Sep. 30, 2024. The entirety of the above-mentioned patent application is hereby incorporated by reference herein and made a part of this specification.

### BACKGROUND

### Field of the Invention

At least an embodiment of the present invention relates to a transport robot.

### Description of the Related Documents

Japanese Unexamined Patent Application Laid-Open No. 2019-111614 (hereinafter, Patent Document 1) describes a work inversion device for delivering a workpiece between a plurality of holding devices. The workpiece inversion device in Patent Document 1 includes the plurality of holding devices each including a suction portion, wherein in a state where one side of the workpiece is suctioned, and the other side of the workpiece is suctioned by a suction portion of another holding device so that the workpiece is delivered among the plurality of holding devices to be transported.

Generally, a thin plate-like workpiece such as a semiconductor wafer is contained in a state such the workpiece is placed on a shelf of a cassette case. Japanese Unexamined Patent Application Laid-Open No. 2013-030703 (hereinafter, Patent Document 2) describes a transport robot for retrieving a wafer contained in a cassette held by a wafer ring, from the cassette, and transporting the wafer. A transport hand includes a chuck mechanism that grips the wafer ring with clamping an edge portion thereof.

When a workpiece such as a wafer contained in a cassette case is retrieved from a cassette and transported to a stage of a processing device, the workpiece may desirably be placed onto the stage from above. However, when the workpiece is retrieved from the cassette case, if an end portion of the workpiece is clamped by the chuck mechanism to retrieve the workpiece as in Patent Document 2, it is not possible to directly place the workpiece onto the stage from above.

Therefore, it is conceivable that after the workpiece is retrieved from the cassette by the hand including the chuck mechanism, the workpiece is suctioned from above by the hand or the like including a suction portion to be transported. However, if the chuck mechanism is simply opened after the workpiece gripped by the chuck mechanism is suctioned, the workpiece interferes with the chuck mechanism when the hand with which the workpiece is suctioned is lifted or lowered.

In view of the above, an aspect of at least an embodiment of the present invention is to prevent a workpiece from interfering with a chuck mechanism when an end portion of the workpiece is clamped by the chuck mechanism and retrieved from a cassette, and thereafter, the workpiece is suctioned and moved up and down.

### SUMMARY

One aspect of a transport robot according to at least an embodiment of the present invention includes a first hand including a chuck mechanism to clamp and hold an outer peripheral end portion of a workpiece, and a first movement mechanism to move the first hand to an advancing position at which the workpiece contained in a workpiece container is holdable and a retreating position farther from the work container than the advancing position, in which when a direction connecting the retreating position and the advancing position is defined as a first direction, a direction from the retreating position toward the advancing position is defined as a first side in the first direction, and a direction from the advancing position toward the retreating position is defined as a second side in the first direction, the chuck mechanism includes a chuck portion openable and closable vertically, and a movement mechanism to move the chuck portion in the first direction.

### BRIEF DESCRIPTION OF THE DRAWINGS

Embodiments will now be described, by way of example only, with reference to the accompanying drawings which are meant to be exemplary, not limiting, and wherein like elements are numbered alike in several figures, in which:

FIG. 1 is a perspective view of a transport robot;

FIG. 2 is a front view of the transport robot;

FIG. 3 is a diagram for illustrating an operation for retrieving a workpiece from a cassette case by the transport robot;

FIG. 4 is an exploded perspective view of a first hand unit and a second hand unit;

FIG. 5 is an exploded perspective view illustrating a state wherein a workpiece is held by the first hand unit and the second hand unit;

FIG. 6 is a diagram for explaining an operation when the workpiece is delivered from the first hand unit to the second hand unit;

FIG. 7 is a plan view illustrating a state wherein a chuck mechanism is opened;

FIG. 8 is a plan view illustrating a state wherein the chuck mechanism is closed;

FIG. 9 is a perspective view of the chuck mechanism and a support member;

FIG. 10 is an exploded perspective view of the chuck mechanism and the support member;

FIG. 11 is a side view of a chuck portion and a cam mechanism; and

FIG. 12 is a diagram for illustrating operations of the chuck portion and the cam mechanism.

### DETAILED DESCRIPTION

With reference to the drawings, an embodiment of a transport robot to which at least an embodiment of the present invention is applied will be described.

### Overall Configuration

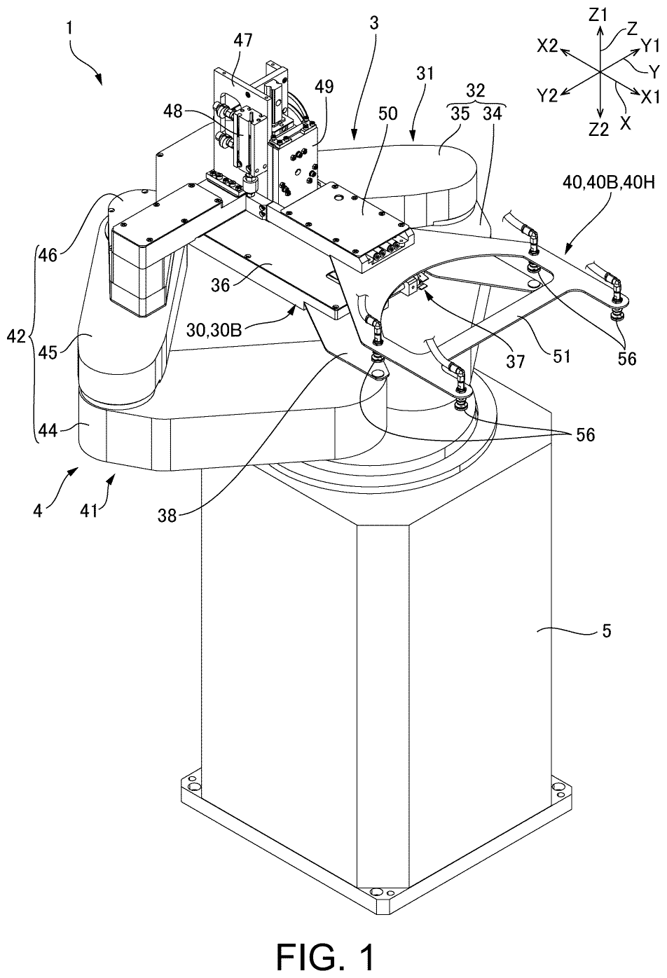

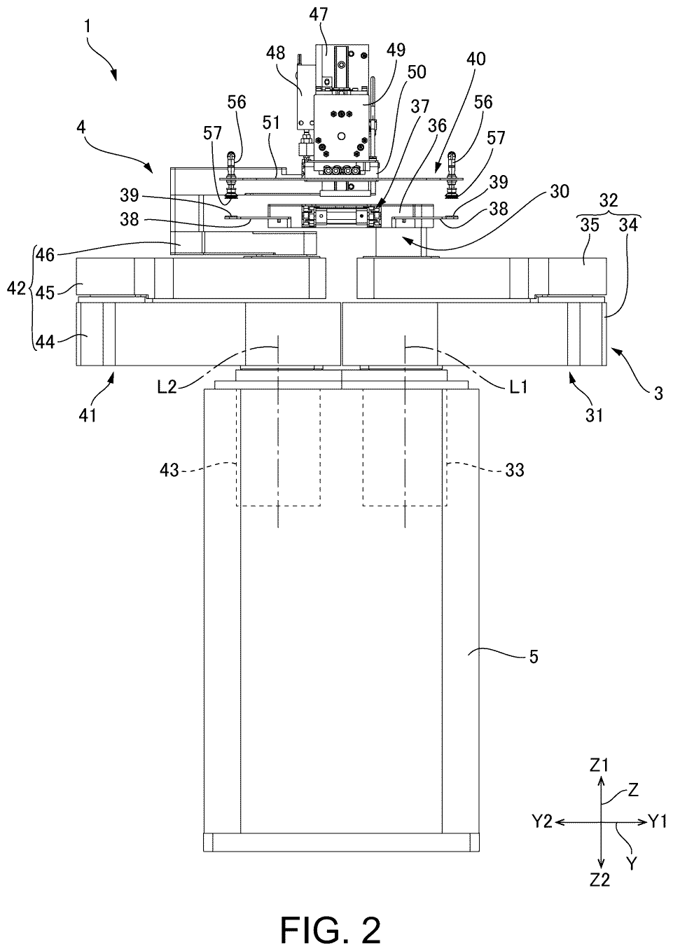

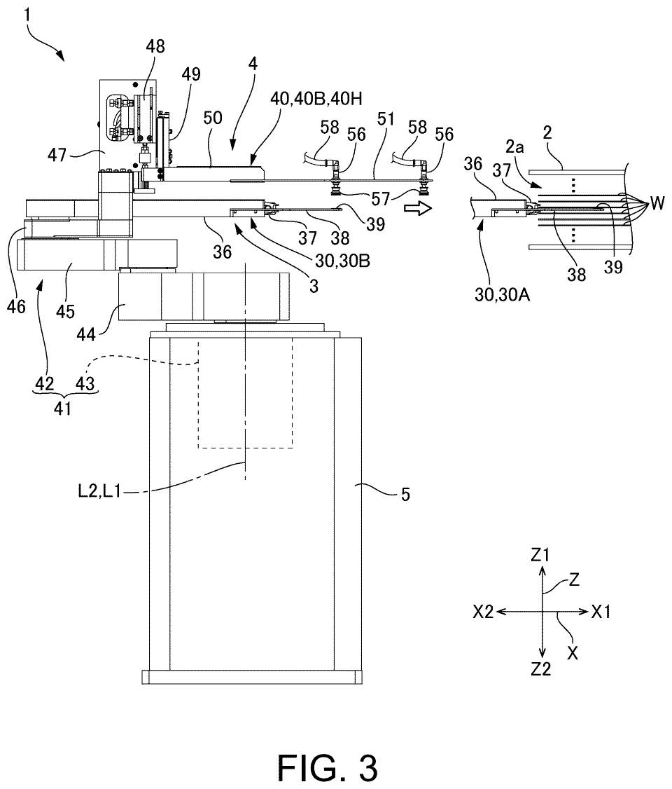

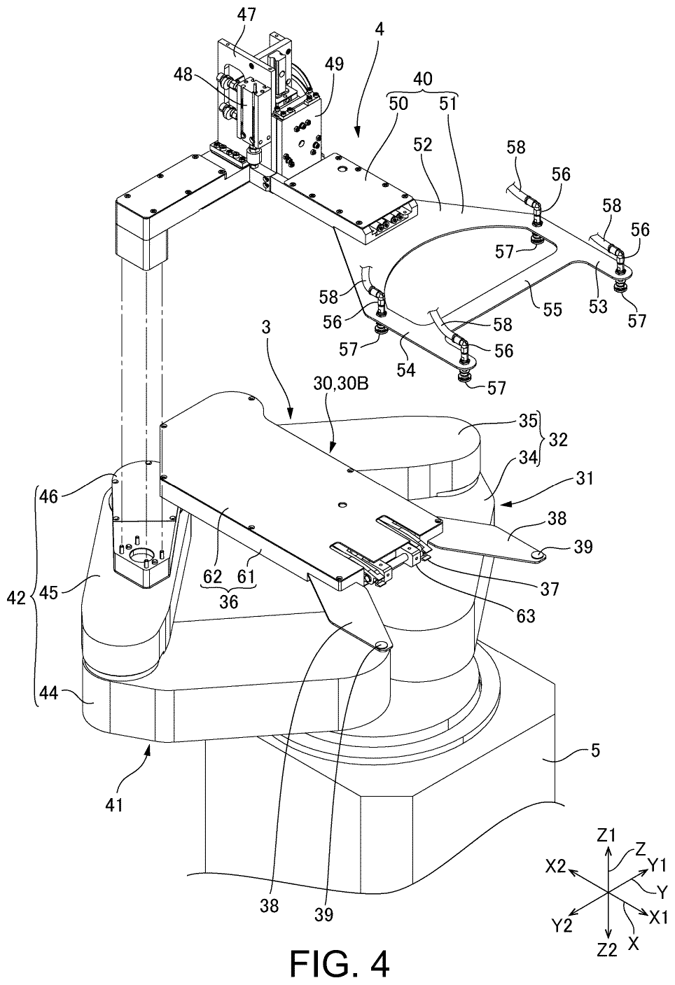

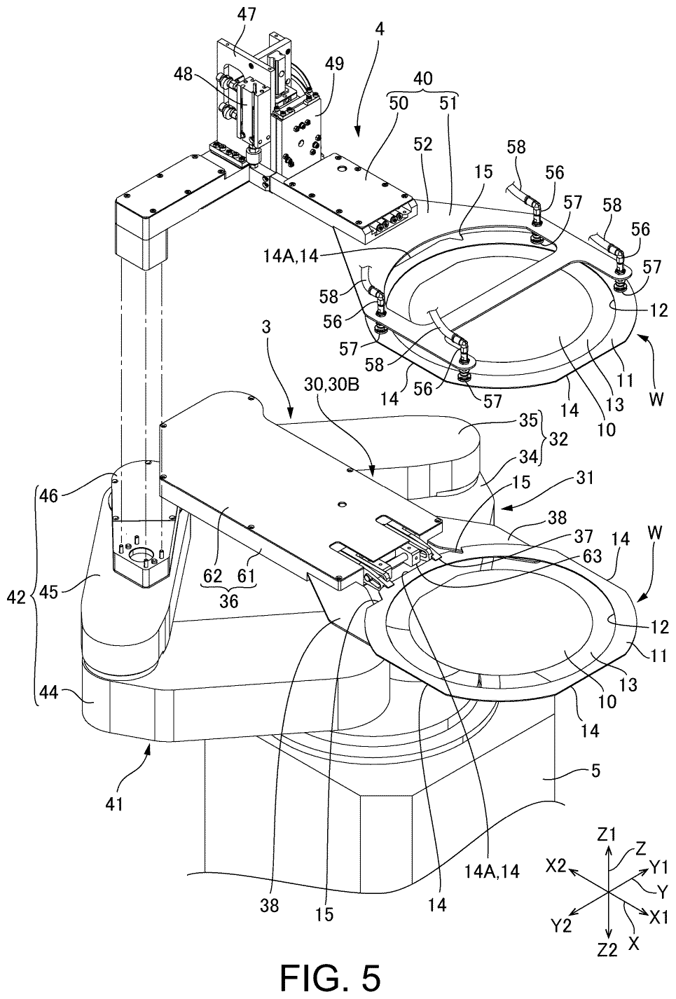

FIG. 1 is a perspective view of a transport robot 1. FIG. 2 is a front view of the transport robot 1. FIG. 3 is a diagram for illustrating an operation for retrieving a workpiece W from a cassette case 2 by the transport robot 1. FIG. 4 is an exploded perspective view of a first hand unit 3 and a second hand unit 4. FIG. 5 is an exploded perspective view illustrating a state wherein the workpiece W is held by the first hand unit 3 and the second hand unit 4.

As used herein, three directions, that is, an X direction, a Y direction, and a Z direction, are perpendicular to each other. One side in the X direction is defined as an X1 direction, and the other side in the X direction is defined as an X2 direction. One side in the Y direction is defined as a Y1 direction, and the other side in the Y direction is defined as a Y2 direction. One side in the Z direction is defined as a Z1 direction, and the other side in the Z direction is defined as a Z2 direction. An XY plane is a horizontal plane. The Z direction is an up-down direction (vertical direction). The Z1 direction is upward. The Z2 direction is downward.

In the following description, the Z direction in the drawing will be referred to as an “up-down direction”, the Z1 direction will be referred to as an “upper” direction, and the Z2 direction will be referred to as a “lower” direction. The X direction is a first direction. The X1 direction is one side in the first direction. The X2 direction is the other side in the first direction. The Y direction is a second direction.

As illustrated in FIG. 3, the transport robot 1 performs an operation for retrieving the workpiece W contained in the cassette case 2. As illustrated in FIG. 5, the workpiece W is a semiconductor wafer 10 (hereinafter referred to as a “wafer 10”) held by a flat plate-like wafer ring 11. The wafer 10 is attached to a center of an adhesive sheet 13 that closes a circle-shaped opening portion 12 provided in a center of the wafer ring 11. As illustrated in FIG. 5, the wafer ring 11 has an outer peripheral edge provided with linearly cut-out straight line portions 14 at four locations.

One of the straight line portions 14 of the wafer ring 11 is a first straight line portion 14A provided with cutout portions 15 on both circumferential sides. One of the remaining three straight line portions 14 is arranged at a position radially opposite to the first straight line portion 14A and extends parallel to the first straight line portion 14A. The remaining two straight line portions 14 extend in a direction perpendicular to the first straight line portion 14A and are arranged at positions opposite each other in a radial direction.

As illustrated in FIG. 3, the cassette case 2 includes a workpiece container 2a wherein a plurality of the workpieces W are vertically arranged at a constant pitch to be contained. Inside the cassette case 2, a placement portion (not illustrated) such as a shelf on which the wafer ring 11 for the workpieces W is placed is arranged vertically at a constant pitch. The workpiece W is contained in the cassette case 2 with the first straight line portion 14A of the wafer ring 11 facing a side of the opening portion of the cassette case 2.

The transport robot 1 is used in a semiconductor manufacturing system. The semiconductor manufacturing system includes, for example, a processing device (not illustrated) to process the wafer 10, the transport robot 1, and a control device (not illustrated) to control the transport robot 1. The transport robot 1 transports the workpiece W, based on a command from the control device. For example, the transport robot 1 performs an operation for placing the workpiece W retrieved from the cassette case 2 onto a stage of the processing device. The transport robot 1 also performs an operation such as an operation for transporting the workpiece W from the stage on which the workpiece W is placed, to another stage, and an operation for unloading the workpiece W from the stage on which the workpiece W is placed.

As illustrated in FIG. 1, FIG. 2 and FIG. 3, the transport robot 1 includes the first hand unit 3, the second hand unit 4, and a support table 5 to support the first hand unit 3 and the second hand unit 4. As illustrated in FIG. 2, the first hand unit 3 and the second hand unit 4 are arranged side by side in the Y direction. The first hand unit 3 is arranged on a Y1 side, and the second hand unit 4 is arranged on a Y2 side.

As illustrated in FIG. 3, the first hand unit 3 performs an operation for unloading the workpiece W contained in the cassette case 2. The transport robot 1 performs an operation for delivering the workpiece W held by the first hand unit 3 to the second hand unit 4. The second hand unit 4 performs an operation for transporting the workpiece W in a state where the workpiece W is suctioned and held from above, and placing the workpiece W onto the stage of the processing device from above.

The support table 5 includes a pivoting mechanism (not illustrated) that pivots a whole of the first hand unit 3 and the second hand unit 4 about a rotation axis extending in the up-down direction. It is noted that the support table 5 may include a lifting and lowering mechanism to lift and lower the whole of the first hand unit 3 and the second hand unit 4. The support table 5 may be fixed to a base to support the support table 5, or may include a mechanism for moving the support table 5 horizontally along a rail provided on the base.

### First Hand Unit

As illustrated in FIG. 1 and FIG. 2, the first hand unit 3 includes a first hand 30 and a first movement mechanism 31 to move the first hand 30. The first movement mechanism 31 includes a first multi-joint arm 32 to move the first hand 30 within a horizontal plane, and a first driving mechanism 33 to drive the first multi-joint arm 32. As illustrated in FIG. 2, the first driving mechanism 33 is provided inside the support table 5. The first driving mechanism 33 includes, for example, a motor serving as a drive source, and a drive force transmission mechanism to reduce a rotation of the motor and transmit the reduced rotation to the first multi-joint arm 32.

As illustrated in FIG. 2 and FIG. 4, the first multi-joint arm 32 includes a first arm 34 coupled to an output shaft of the first driving mechanism 33, and a second arm 35 coupled to the first arm 34. When the first arm 34 rotates around a rotation axis line L1 extending in the up-down direction and the second arm 35 rotates in conjunction with the first arm 34, the first multi-joint arm 32 configures a link mechanism to extend and contract in the X direction, as a whole. When the first multi-joint arm 32 extends and contracts in the X direction, the first hand 30 moves linearly in the X direction while the first hand 30 maintains a posture with a distal end thereof facing the X1 direction.

The first hand unit 3 extends the first multi-joint arm 32 in the X1 direction toward the cassette case 2 to unload workpiece W out. As illustrated in FIG. 3, the first movement mechanism 31 moves the first hand 30 to an advancing position 30A where a distal end portion of the first hand 30 is inserted into the cassette case 2, and to a retreating position 30B where the first hand 30 is retreated to above the support table 5. The retracting 10) position 30B is a position farther away from the cassette case 2 than the advancing position 30A.

As illustrated in FIG. 4 and FIG. 5, the first hand 30 includes a first hand main body 36 coupled to a distal end of the first multi-joint arm 32, a chuck mechanism 37 arranged at an end portion of the first hand body 36 in the X1 direction, and a pair of first plates 38 extending in the X1 direction from both sides of the chuck mechanism 37 in the Y direction. The pair of first plates 38 are workpiece supporting portions to support the workpiece W from below. Each of the first plates 38 is formed of, for example, a ceramic plate. A circle-shaped pad 39 is attached to each of distal ends of the pair of first plates 38. The pad 39 is formed of an insulating resin such as polyether ether ketone (PEEK). The chuck mechanism 37 will be described in detail below.

As illustrated in FIG. 3, the first hand unit 3 extends the first multi-joint arm 32 with a distal end of the chuck mechanism 37 open, and moves the first hand 30 to the advancing position 30A. As a result, the first plate 38 is inserted under the workpiece W contained in the cassette case 2. An outer peripheral end portion of the workpiece W is inserted between the distal ends of the chuck mechanisms 37. When the distal end of the chuck mechanism 37 is closed in such a state, the outer peripheral end portion of the workpiece W is clamped and held by the chuck mechanism 37. Thereafter, the first multi-joint arm 32 is bent to retract the first hand 30 to the retreating position 30B. As a result, the workpiece W is unloaded outside of the cassette case 2.

As illustrated in FIG. 5, the workpiece W unloaded from the cassette case 2 is held by the first hand 30 with both end portions of the wafer ring 11 in the Y direction being supported by the first plate 38, and with the first straight line portion 14A of the wafer ring 11 being clamped by the chuck mechanism 37. The wafer ring 11 is supported by the first plate 38 via the pad 39 attached to a distal end of the first plate 38.

### Second Hand Unit

As illustrated in FIG. 1 and FIG. 2, the second hand unit 4 includes a second hand 40 and a second movement mechanism 41 to move the second hand 40. The second movement mechanism 41 includes a second multi-joint arm 42 to move the second hand 40 within a horizontal plane, and a second driving mechanism 43 to drive the second multi-joint arm 42. As illustrated in FIG. 2, the second driving mechanism 43 is provided inside the support table 5. The second driving mechanism 43 includes, for example, a motor serving as a drive source, and a drive force transmission mechanism to reduce a rotation 10) of the motor and transmit the reduced rotation to the second multi-joint arm 42.

As illustrated in FIG. 2 and FIG. 4, the second multi-joint arm 42 includes a first arm 44 coupled to an output shaft of the second driving mechanism 43, a second arm 45 coupled to the first arm 44, a third arm 46 coupled to the second arm 45, and a second hand support portion 47 coupled to a distal end of the third arm 46. When the first arm 44 rotates around a rotation axis line L2 extending in the Z direction and the second arm 45 and the third arm 46 rotate in conjunction with the first arm 44, the second multi-joint arm 42 configures a link mechanism that extends and contracts in the X direction as a whole. When the second multi-joint arm 42 extends and contracts in the X direction, the second hand 40 moves linearly in the X direction while the second hand 40 maintains a posture with a distal end thereof facing the X1 direction. In moving the second hand 40 toward the stage of the processing device, the second multi-joint arm 42 can also perform an operation for extending a distal end thereof in a direction different from the X direction within an XY plane.

As illustrated in FIG. 1, FIG. 2, and FIG. 3, the second hand 40 is located above the first hand 30. As illustrated in FIG. 1, the second movement mechanism 41 can bend the second multi-joint arm 42 to move the second hand 40 to a delivery position 40B at which to overlap from above with the first hand 30 that moves to the retreating position 30B.

The second hand support portion 47 includes a lifting and lowering mechanism 48 and a hand adjustment mechanism 49. The second hand 40 is coupled to a distal end of the second multi-joint arm 42 via the lifting and lowering mechanism 48 and the hand adjustment mechanism 49. The lifting and lowering mechanism 48 moves the second hand 40 in the up-down direction. The lifting and lowering mechanism 48 is, for example, a linear motion mechanism such as a cylinder. As described above, the second hand 40 is located above the first hand 30, and thus, when the second hand 40 descends, the second hand 40 approaches the first hand 30, and when the second hand 40 ascends, the second hand 40 moves away from the first hand 30.

As illustrated in FIG. 1 and FIG. 4, the second hand 40 includes a second hand main body 50 located in the X1 direction of the second hand support portion 47, a second frame 51 extending in the X1 direction from the second hand main body 50, and a plurality of suction portions 56 arranged on the second frame 51. Each of the plurality of suction portions 56 is connected to a suction device (not illustrated) via an air tube 58 routed above the second frame 51.

As illustrated in FIG. 4, each of the suction portions 56 includes a suction pad 57 that protrudes downward from the second frame 51. The suction pad 57 is formed of a resin such as fluororubber. When the second hand 40 suctions the workpiece W held by the first hand 30, a distal end surface of the suction pad 57 is brought into close contact with a surface of the wafer ring 11, and then the suction device is driven. As a result, the workpiece W is suctioned to the suction pad 57 as illustrated in FIG. 5. The hand adjustment mechanism 49 is a mechanism for adjusting a position and an inclination of the second hand 40 by taking into account a deflection of the workpiece W held by the first hand 30 so that the workpiece W can be suctioned by the plurality of suction portions 56.

As illustrated in FIG. 4, the second frame 51 includes a hand base portion 52 protruding from the second hand main body 50 in the X1 direction and extending to both sides in the Y direction, a first frame portion 53 extending in the X1 direction from an end portion of the hand base portion 52 in the Y1 direction, a second frame portion 54 extending in the X1 direction from and end portion of the hand base portion 52 in the Y2 direction, and a third frame portion 55 extending in the Y direction and connecting the first frame portion 53 and the second frame portion 54. The third frame portion 55 is connected to a center of the first frame portion 53 and the second frame portion 54 in the X direction. The second frame 51 is formed of, for example, a ceramic plate.

The second hand 40 includes the suction portions 56 at four locations. Of the suction portions 56 at the four locations, the two suction portions 56 are arranged on both ends of the first frame portion 53 in the X direction, and the other two suction portions 56 are arranged on both ends of the second frame portion 54 in the X direction. Therefore, of the suction portions 56 at the four locations, the two suction portions 56 are arranged at distal ends of the first frame portion 53 and the second frame portion 54. The suction portions 56 at the other two locations are arranged at positions where the first frame portion 53 and the second frame portion 54 are connected to the hand base portion 52. Of the four suction portions 56, the two suction portions 56 are arranged at a position overlapping from above with a distal end of the first plate 38 when the first hand 30 moves to the retreating position 30B and the second hand 40 moves to the delivery position 40B, as illustrated in FIG. 1. As described above, the distal end of the first plate 38 is arranged with the pad 39 on which the workpiece W is placed. Therefore, of the suction portions 56 at the four locations, the two suction portions 56 are arranged at positions overlapping from above with the pad 39.

### Operation for Delivering Workpiece W

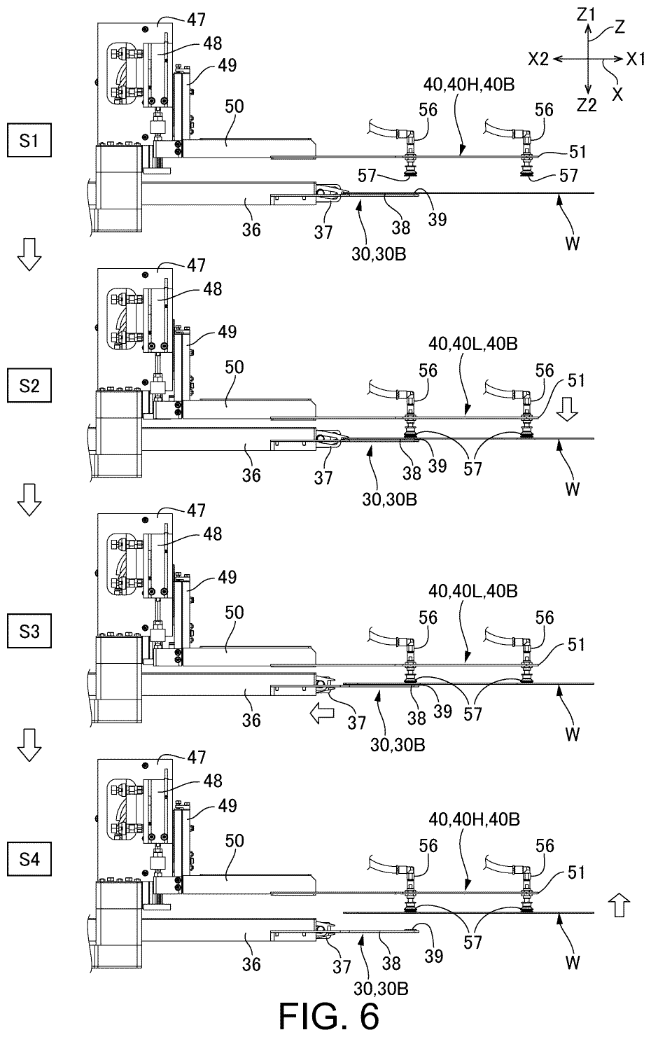

FIG. 6 is a diagram for explaining an operation when the workpiece W is delivered from the first hand unit 3 to the second hand unit 4. The transport robot 1 retrieves the workpiece W from the cassette case 2 by the first hand unit 3, and thereafter, preforms an operation for delivering the workpiece W from the first hand unit 3 to the second hand unit 4. Specifically, the first hand unit 3 and the second hand unit 4 are operated in an order of steps S1, S2, S3, and S4 in FIG. 6.

First, in step S1, the first hand 30 holding the workpiece W is moved to the retreating position 30B, and the second hand 40 is moved to the delivery position 40B. At this time, the lifting and lowering mechanism 48 lifts the second hand 40 to a lifted position 40H illustrated in FIG. 6. The lifted position 40H is a position where the suction pad 57 of the second hand 40 is separated from the workpiece W.

Next, in step S2, the second hand 40 is lowered to a lowered position 40L illustrated in FIG. 6, and the suction pad 57 of the suction portions 56 at the four locations is brought into close contact with a surface of the workpiece W. In the present embodiment, the suction pads 57 at the four locations are brought into close contact with a surface of the wafer ring 11. Next, the suction device is driven so that the wafer ring 11 is suctioned.

As a result, the workpiece W is held by the first hand 30 and also held by the second hand 40.

Next, in step S3, the distal end portion of the chuck mechanism 37 of the first hand 30 is opened up and down, and the distal end portion of the chuck mechanism 37 is moved in the X2 direction to be retracted into the first hand main body 36. As a result, a state is realized where the chuck mechanism 37 does not vertically overlap the outer peripheral end portion of the workpiece W. The workpiece W is not held by the chuck mechanism 37, but is placed on the first plate 38 and is suctioned by the second hand 40.

Finally, in step S4, the lifting and lowering mechanism 48 is driven to lift the second hand 40 with which the workpiece W is suctioned, to the lifted position 40H. At this time, the distal end portion of the chuck mechanism 37 is retracted in the X2 direction, and thus, the workpiece W can be lifted without interfering with the chuck mechanism 37. Thus, the delivery of the workpiece W from the first hand 30 to the second hand 40 is completed.

After the workpiece W is delivered to the second hand unit 4, the transport robot 1 performs an operation for placing the workpiece W on the stage of the processing device from above. For example, the transport robot 1 performs some or all of operations including an operation for pivoting a whole of the second hand unit 4 around the support table 5, an operation for extending and contracting the second multi-joint arm 42, and an operation for lifting and lowering, by the lifting and lowering mechanism 48, the second hand 40 relative to the second multi-joint arm 42 in combination. It is noted that an operation for lifting and lowering the whole of the second hand unit 4 relative to the support table 5 may be combined.

### Chuck Mechanism

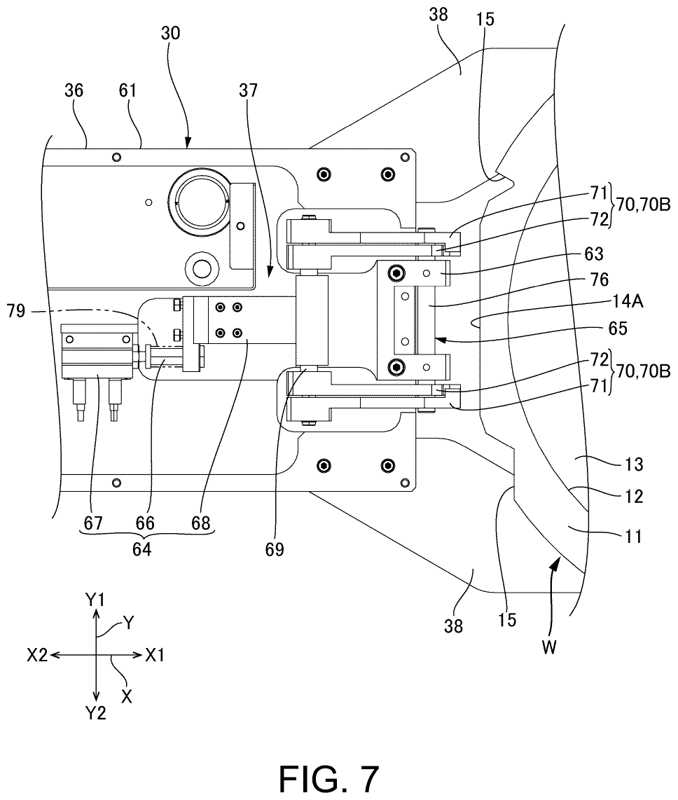

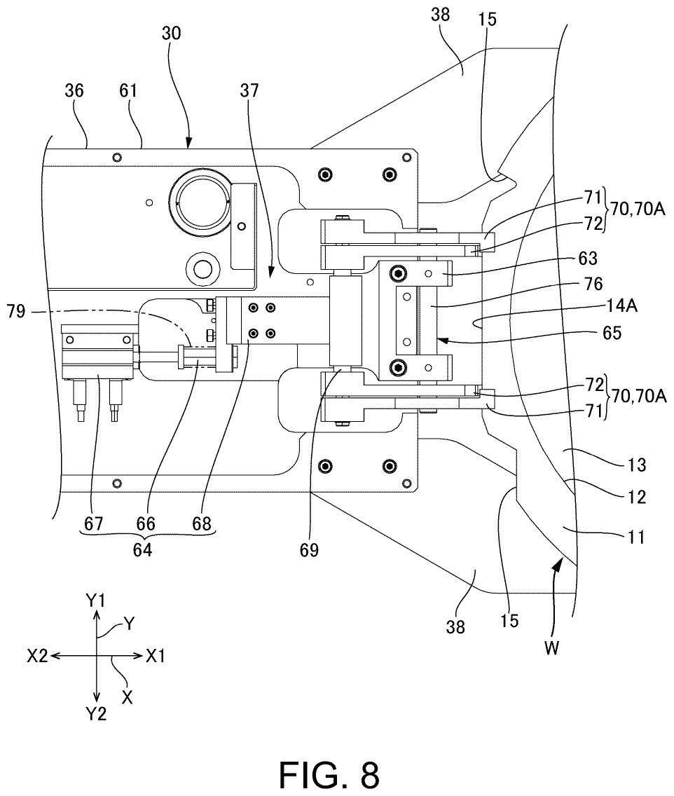

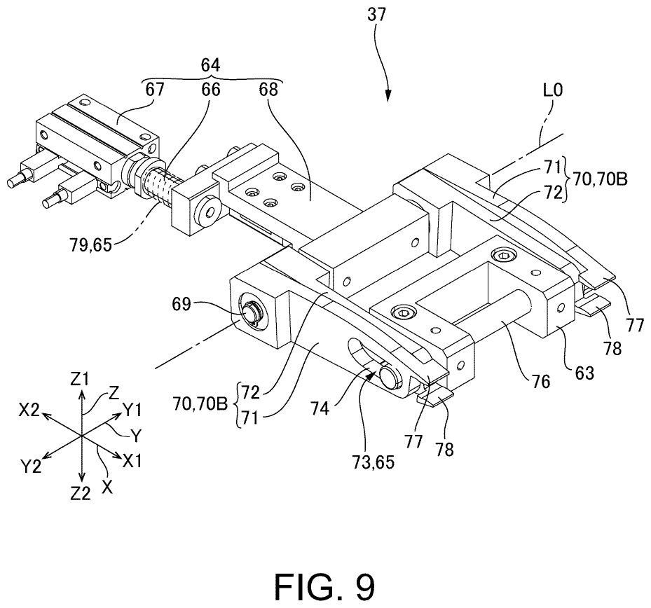

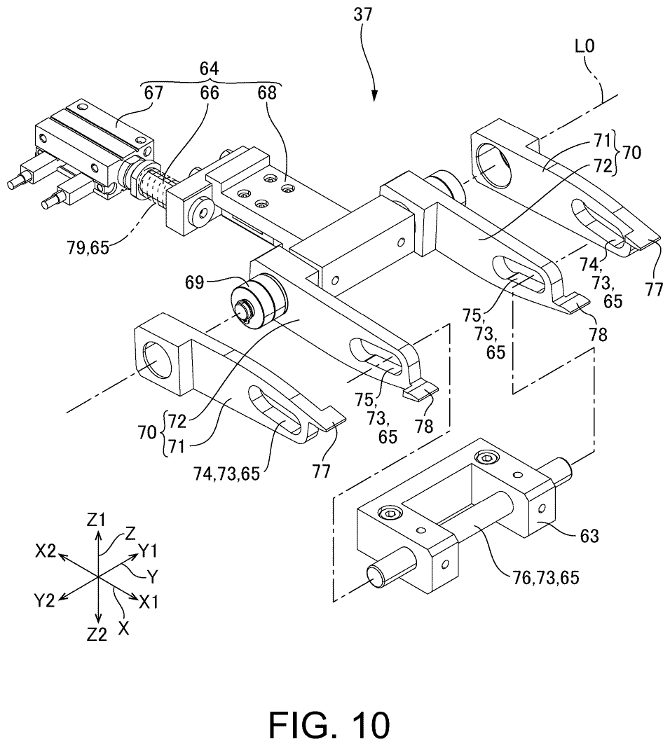

FIG. 7 is a plan view illustrating a state where the chuck mechanism 37 is opened. FIG. 8 is a plan view illustrating a state wherein the chuck mechanism 37 is closed. FIG. 9 is a perspective view of the chuck mechanism 37 and the support member 63. FIG. 10 is an exploded perspective view of the chuck mechanism 37 and the support member 63.

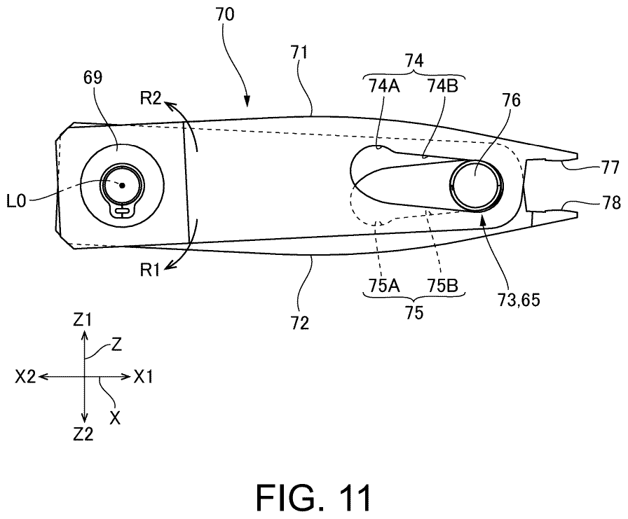

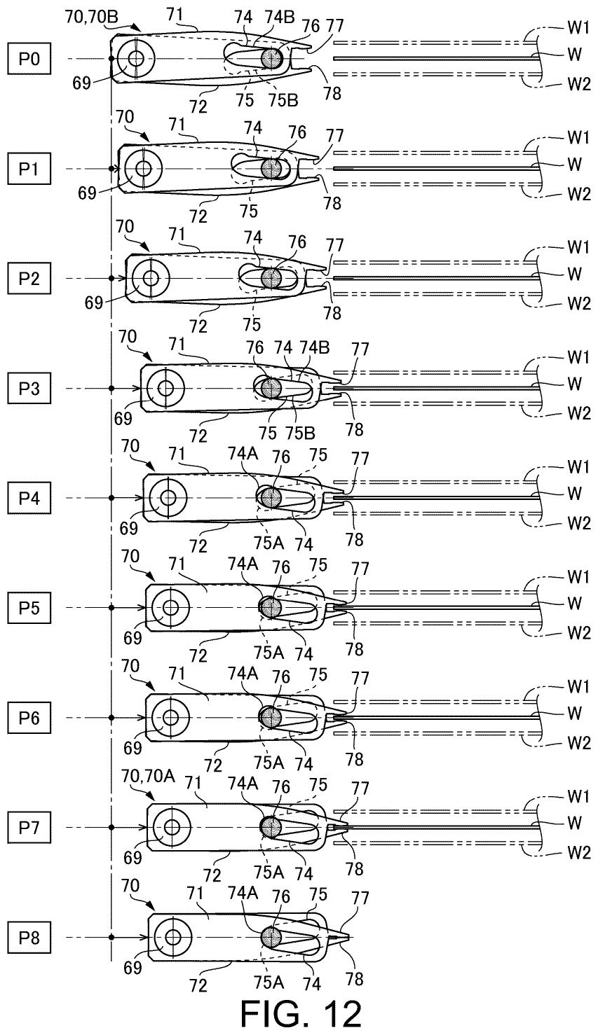

FIG. 11 is a side view of a chuck portion 70 and a cam mechanism 73. FIG. 12 is a diagram for illustrating operations of the chuck portion 70 and the cam mechanism 73.

As illustrated in FIG. 4 and FIG. 5, the first hand main body 36 of the first hand 30 includes a hand housing 61 that houses the chuck mechanism 37 therein, a cover 62 fixed to an upper end of the hand housing 61, and a support member 63 fixed to an end portion of the hand housing 61 in the X1 direction. FIG. 7 and FIG. 8 are plan views obtained when the first hand 30 is viewed from above with the cover 62 removed from the hand housing 61. The chuck mechanism 37 includes the chuck portion 70 having a distal end portion in the X1 direction being openable and closable vertically, a movement mechanism 64 to move the chuck portion 70 in the X direction relative to the hand housing 61, and an opening and closing mechanism 65 to open and close the chuck portion 70.

As illustrated in FIG. 7, FIG. 8, FIG. 9, and FIG. 10, the movement mechanism 64 includes a cylinder 67 provided with a rod 66 protruding in the X1 direction, and a slider 68 coupled to a distal end of the rod 66. As illustrated in FIG. 10, the chuck portion 70 includes a spindle 69 extending in the Y direction, and a first chuck member 71 and a second chuck member 72 rotatably coupled to the spindle 69.

The spindle 69 of the chuck portion 70 is fixed to the slider 68 and protrudes from the slider 68 toward both sides in the Y direction. The chuck portion 70 includes a set of the chuck portions 70 arranged on each of both ends of the spindle 69 in the Y direction. Therefore, the both ends of the spindle 69 in the Y direction are each coupled with a set of the first chuck member 71 and the second chuck member 72, respectively. The first chuck member 71 and the second chuck member 72 rotate about a rotation axis line L0 passing through a center of the spindle 69 and extending in the Y direction.

When the movement mechanism 64 drives the cylinder 67 to extend the rod 66 in the X1 direction, the slider 68 is advanced in the X1 direction. As a result, the two sets of chuck portions 70 advance in the X1 direction at the same time. As illustrated in FIG. 8, the movement mechanism 64 advances the two sets of chuck portions 70 to a gripping position 70A where a distal end of the chuck portion 70 vertically overlaps an outer peripheral end portion of the workpiece W. On the other hand, when the cylinder 67 is driven to draw the rod 66 into the X2 direction, the two sets of chuck portions 70 are retreated in the X2 direction via the slider 68. As illustrated in FIG. 7, the movement mechanism 64 retracts the two sets of chuck portions 70 to an open position 70B where the distal end of the chuck portion 70 is located close to the X2 direction relative to the outer peripheral end portion of the workpiece W.

The opening and closing mechanism 65 opens and closes the two sets of chuck portions 70 simultaneously. As illustrated in FIG. 9, the opening and closing mechanism 65 includes a cam mechanism 73 and a spring 79 attached to an outer periphery of the rod 66 of the movement mechanism 64. A function of the spring 79 will be described below. The cam mechanism 73 causes the chuck portion 70 to perform an opening and closing operation by the chuck portion 70 being moved in the X direction. Specifically, the cam mechanism 73 causes the chuck portion 70 to perform an operation for closing the distal end portion when the chuck portion 70 moves in the X1 direction, and causes the chuck portion 70 to perform an operation for opening the distal end portion when the chuck portion 70 moves in the X2 direction. Therefore, when the chuck portion 70 moves to the gripping position 70A, the distal end of the chuck portion 70 is in the most tightly closed state. When the chuck portion 70 moves to the open position 70B, the distal end of the chuck portion 70 is in the most widely opened state. FIG. 9 shows a state where the distal end of the chuck portion 70 is in the most widely opened state.

As illustrated in FIG. 10 and FIG. 11, the cam mechanism 73 includes a first cam groove 74 formed in the first chuck member 71, a second cam groove 75 formed in the second chuck member 72, and a cam pin 76 that moves inside the first cam groove 74 and the second cam groove 75. As illustrated in FIG. 9 and FIG. 10, the cam pin 76 is attached to penetrate the support member 63 fixed to the distal end of the hand housing 61. The support member 63 is arranged between the two sets of chuck portions 70. Both ends of the cam pin 76 protruding from the support member 63 into both sides in the Y direction are inserted into the first cam groove 74 and the second cam groove 75, respectively.

As illustrated in FIG. 10 and FIG. 11, the first cam groove 74 and the second cam groove 75 both extend along the X direction and are inclined in directions opposite to the X direction. The first cam groove 74 is inclined downward (in the Z2 direction) toward the X1 direction. On the other hand, the second cam groove 75 is inclined upward (in the Z1 direction) toward the X1 direction.

When the cylinder 67 is driven to project the rod 66 and advances the chuck portion 70 into the X1 direction, the cam pin 76 moves inside the first cam groove 74 and the second cam groove 75 in the X2 direction. As a result, the first chuck member 71 rotates in a first rotation direction R1 illustrated in FIG. 11, and a first claw portion 77 provided at the distal end of the first chuck member 71 in the X1 direction descends. Meanwhile, the second chuck member 72 rotates in a second rotation direction R2 opposite to the first rotation direction R1, and a second claw portion 78 provided at the distal end of the second chuck member 72 in the X1 direction ascends in the Z1 direction. Therefore, as a result of the chuck portion 70 advancing in the X1 direction, the distal end of the chuck portion 70 is closed and the first claw portion 77 and the second claw portion 78 approach each other. When the cylinder 67 draws the rod 66 to retreat the chuck portion 70 into the X2 direction, an operation opposite to that described above is performed, and the distal end of the chuck portion 70 is opened and the first claw portion 77 and the second claw portion 78 are separated from each other.

### Cam Groove Shape

As illustrated in FIG. 11, the first cam groove 74 includes a first region 74A provided at an end of the first cam groove 74 in the X2 direction, and a second region 74B which is a region close to the X1 direction relative to the first region 74A. Similarly, the second cam groove 75 includes a first region 75A provided at an end of the second cam groove 75 in the X2 direction, and a second region 75B which is a region close to the X1 direction relative to the first region 75A.

As can be seen from FIG. 11, the second region 74B and the second region 75B have a constant inclination angle relative to the X direction and extend linearly. On the other hand, the first region 74A has a larger inclination angle relative to the X direction than the second region 74B. More specifically, the first region 74A is curved in such a direction that the inclination angle relative to the X direction increases toward the end of the first cam groove 74 in the X2 direction. Similarly, the first region 75A has a larger inclination angle relative to the X direction than the second region 75B. More specifically, the first region 75A is curved in such a direction that the inclination angle relative to the X direction increases toward the end of the second cam groove 75 in the X2 direction.

The inclination angles of the first cam groove 74 and the second cam groove 75 correspond to a speed at which the chuck portion 70 opens and closes, in other words, a speed at which the first claw portion 77 and the second claw portion 78 move close to or move away from each other. When the inclination angle of the first cam groove 74 and the second cam groove 75 relative to the X direction is large, the speed at which the first claw portion 77 and the second claw portion 78 move close to or move away from each other is fast. In the present embodiment, as described above, the first cam groove 74 and the second cam groove 75 are both shaped so that the inclination angle relative to the X direction increases toward the end in the X2 direction. Therefore, when the chuck portion 70 closes, the chuck portion 70 closes slowly at first, but then closes at the fastest speed in a final stage of clamping the workpiece W.

FIG. 12 is a diagram for illustrating operations of the chuck portion 70 and the cam mechanism 73. In FIG. 12, W indicates the workpiece to be clamped by the chuck portion 70. W1 and W2 indicate the workpieces above and below the workpiece W. P0 to P8 in FIG. 12 illustrate a process wherein the cam pin 76 moves through an entire range of the first cam groove 74 and the second cam groove 75. P0 illustrates a state where the chuck portion 70 is located at the open position 70B. A section from P0 to P3 is a section where the cam pin 76 moves through the second region 74B and the second region 75B. A section from P3 to P8 is a section where the cam pin 76 moves through the first region 74A and the first region 75A.

As described above, the second region 74B and the second region 75B have a small inclination angle relative to the X direction, and thus, a speed at which the first claw portion 77 and the second claw portion 78 close is slow compared to an amount of movement in the X direction. Therefore, as can be seen from a state of P3, the outer peripheral end portion of the workpiece W is inserted between the first claw portion 77 and the second claw portion 78 while a gap between the first claw portion 77 and the second claw portion 78 is still wide. At this time, the positions of the first claw portion 77 and the second claw portion 78 are such that a predetermined gap can be secured between upper and lower workpieces W1, W2.

On the other hand, the first region 74A and the first region 75A are curved in a direction wherein the inclination angle relative to the X direction increases, and thus, in the section from P3 to P8, the first claw portion 77 and the second claw portion 78 close abruptly even if the amount of movement in the X direction is small. P7 illustrates a state where the workpiece W is clamped between the first claw portion 77 and the second claw portion 78. P8 illustrates a state where the chuck portion 70 is closed until the first claw portion 77 and the second claw portion 78 come into contact with each other when there is no workpiece W between the first claw portion 77 and the second claw portion 78.

The workpiece W is clamped between the first jaw portion 77 and the second jaw portion 78, and thus, the chuck portion 70 does not actually close until a state of P8 is reached. As described above, the opening and closing mechanism 65 includes the spring 79 attached to the outer periphery of the rod 66 of the movement mechanism 64, and in a state where the workpiece W is clamped, an elastic force of the spring 79 urges in a direction where the first claw portion 77 and the second claw portion 78 come close to each other. Therefore, the workpiece W is gripped by the first claw portion 77 and the second claw portion 78 by the elastic force of the spring 79.

### Operation and Effect

As described above, the transport robot 1 according to the present embodiment includes the first hand 30 including the chuck mechanism 37 to clamp and hold an outer peripheral end portion of the workpiece W, and the first movement mechanism 31 to move the first hand 30 to the advancing position 30A where the workpiece W contained in the cassette case 2 can be held and to the retreating position 30B farther from the cassette case 2 than the advancing position 30A, in which when a direction connecting the retreating position 30B and the advancing position 30A is defined as an X direction, a direction from the retreating position 30B toward the advancing position 30A is defined as an X1 direction, and a direction from the advancing position 30A toward the retreating position 30B is defined as an X2 direction, the chuck mechanism 37 includes the chuck portion 70 openable and closable vertically, and the movement mechanism 64 to move the chuck portion 70 in the X direction.

Thus, the transport robot 1 according to the present embodiment is capable of not only opening and closing the chuck mechanism 37 to clamp the outer peripheral end of the workpiece W, but also moving the chuck mechanism 37 in the X direction. Therefore, when the workpiece W is delivered to a hand other than the first hand 30, the chuck mechanism 37 can be retracted to a position where the chuck mechanism 37 does not vertically overlap the workpiece W. As a result, it is possible to prevent the workpiece W from interfering with the chuck portion 70 of the first hand 30, for example, when another hand is lifted and lowered to move the workpiece W.

In the present embodiment, the chuck mechanism 37 includes the opening and closing mechanism 65 to open and close the chuck portion 70. The opening and closing mechanism 65 causes the chuck portion 70 to perform a closing operation when the chuck portion 70 moves in the X1 direction, and causes the chuck portion 70 to perform an opening operation when the chuck portion 70 moves in the X2 direction. Thus, when the advancing operation and the retreating operation of the chuck portion 70 and the opening and closing operation of the chuck portion 70 are performed in conjunction, it is possible to perform an operation for clamping the outer peripheral end portion of the workpiece W with the chuck portion 70 being closed while the chuck portion 70 is inserted into the cassette case 2, and an operation for retreating the chuck portion 70 while keeping the chuck portion 70 being opened when the workpiece W is delivered to another hand.

In the present embodiment, the first hand 30 includes the first hand main body 36 to support the chuck mechanism 37. The opening and closing mechanism 65 is the cam mechanism 73 including the cam pin 76 arranged on the first hand main body 36 and the cam groove provided in the chuck portion 70. As a result, it is possible to open and close the chuck portion 70 at an appropriate timing by appropriately setting a shape of the cam groove.

It is noted that when the cam mechanism is used as the opening and closing mechanism 65, it is possible to reverse the arrangement of the cam groove and the cam pin. That is, the cam mechanism may be any mechanism that includes a cam pin arranged in one of the first hand main body 36 and the chuck portion 70, and a cam groove provided on the other of the first hand main body 36 and the chuck portion 70.

In the present embodiment, the first hand 30 includes the first hand main body 36 to support the chuck mechanism 37, and the chuck portion 70 includes the spindle 69 that is moved in the X direction by the movement mechanism 64, and the first chuck member 10) 71 and the second chuck member 72 that are rotatably coupled to the spindle 69. The opening and closing mechanism 65 includes, as the cam groove, the first cam groove 74 arranged in the first chuck member 71, the second cam groove 75 arranged in the second chuck member 72, and the cam mechanism 73 including the cam pin 76 moving inside of the first cam groove 74 and the second cam groove 75. The cam pin 76 is arranged in the first hand main body 36, and the first cam groove 74 and the second cam groove 75 extend in a direction inclined oppositely to the X direction. As a result, when the first chuck member 71 and the second chuck member 72 are rotated in the opposite direction along with the movement of the chuck portion 70 in the X1 direction, it is possible to close the distal end of the chuck portion 70. When the first chuck member 71 and the second chuck member 72, which are closed along with the movement of the chuck portion 70 in the X2 direction, are rotated in the opposite direction, it is possible to open the distal end of the chuck portion 70.

In the present embodiment, the first cam groove 74 and the second cam groove 75 include the first regions 74A and 75A at the end in the X2 direction, and the second regions 74B and 75B close to the X1 direction relative to the first regions 74A and 75A, respectively, and the first regions 74A and 75A have larger inclination angles relative to the X direction than the second regions 74B and 75B. Increasing the inclination angle of the cam groove increases the speed at which the chuck portion 70 closes. Therefore, due to the above-mentioned cam groove shape, when the chuck portion 70 closes, the chuck portion 70 closes slowly at first, but in the final stage of clamping the workpiece W, the chuck portion 70 is capable of performing an operation where the closing speed is fast. With such an operation, it is possible to reduce a risk that when the workpiece W is retrieved from the cassette case 2, the outer peripheral end portion of the workpiece W cannot be inserted between the first chuck member 71 and the second chuck member 72 due to a decrease in positional accuracy in the up-down direction of the workpiece W relative to the chuck portion 70.

In the present embodiment, it is preferable that the inclination angle of the first region 74A relative to the X direction increases toward the X2 direction. Thus, the closing speed can be gradually increased as the operation for clamping the workpiece W approaches the final stage. Therefore, it is possible to further reduce a risk that the outer peripheral end portion of the workpiece W cannot be inserted between the first chuck member 71 and the second chuck member 72 due to a decrease in positional accuracy in the up-down direction of the workpiece W relative to the chuck portion 70.

In the present embodiment, the first hand 30 includes the pair of first plates 38 extending in the X1 direction from the both sides of the chuck mechanism 37 in the Y direction, and the pair of first plates 38 support the workpiece W from below. Thus, when the first plate 38 is combined with the chuck mechanism 37, it is possible to support the workpiece W even if a length of the first plate 38 is shortened. Therefore, even if a stacking interval of the workpieces W is narrow when the workpieces W are contained in the cassette case 2, it is possible to prevent a case where when the workpieces W are retrieved, the first plate 38 is bent and interferes with other workpieces W.

In the present embodiment, the second hand 40 including the suction portion 56 to suction the surface of the workpiece W, the second movement mechanism 41 to move the second hand 40 to the delivery position 40B where the delivery position 40B overlaps vertically with the retreating position 30B, and the lifting and lowering mechanism 48 to lift and lower the second hand 40 moved to the delivery position 40B, are provided. Thus, when the second hand 40 to suction the surface of the workpiece W and the lifting and lowering mechanism are combined, after the outer peripheral end portion of the workpiece W is clamped by the first hand 30 to retrieve the workpiece W from the cassette case 2, it is possible to suction and hold the workpiece W from above by the suction portion 56 of the second hand 40. Therefore, it is possible to place the workpiece W on the stage of the processing device from above without the workpiece W retrieved from the cassette case 2 being turned over.

In the present embodiment, the second movement mechanism 41 is the second multi-joint arm 42 to move the second hand 40 on a horizontal plane, and the lifting and lowering mechanism 48 is arranged at the distal end of the second multi-joint arm 42 and lifts and lowers the second hand 40 relative to the second multi-joint arm 42. Thus, when a multi-joint arm and a lifting and lowering mechanism are combined, it is possible to perform an operation where the workpiece W is suctioned from above and held, and thereafter, the workpiece W is transported to the stage of the processing device, and the workpiece W is placed on the stage from above.

### OTHER EMBODIMENTS

(1) The above-mentioned transport robot 1 includes the second hand 40 to suction the surface of the workpiece W as well as the first hand 30 to clamp and hold the outer peripheral end portion of the workpiece W, but the transport robot 1 may or may not include the second hand 40. If the second hand 40 is not included, when the transport robot 1 delivers the workpiece W to the hand of another robot, the transport robot 1 may retract the chuck portion 70 after the hand of the other robot suctions the surface of the workpiece W. The second hand 40 or the hand of the other robot may include an edge grip chuck mechanism to grip the workpiece W from an outer peripheral side, instead of the suction portion 56 to suction the workpiece W from above.

(2) The above-described transport robot 1 uses the cam mechanism 73 to link the movement of the chuck portion 70 into the X direction with the opening and closing operation of the chuck portion 70. However, the opening and closing mechanism and the movement mechanism may be configured to operate in conjunction with each other through a control.

### SUMMARY

At least an embodiment of the present invention may employ the following forms.

(1)

A transport robot including a first hand including a chuck mechanism to clamp and hold an outer peripheral end portion of a workpiece, and
a first movement mechanism to move the first hand to an advancing position where the workpiece contained in a workpiece container can be held and to a retreating position farther from the workpiece container than the advancing position, in which
when a direction connecting the retreating position and the advancing position is defined as a first direction, a direction from the retreating position toward the advancing position is defined as one side in the first direction, and a direction from the advancing position toward the retreating position is defined as the other side in the first direction,
the chuck mechanism includes a chuck portion openable and closable vertically, and a movement mechanism to move the chuck portion in the first direction.
   (2)

The transport robot according to (1) above, in which the chuck mechanism includes an opening and closing mechanism to open and close the chuck portion, and
the opening and closing mechanism causes the chuck portion to perform a closing operation along with movement of the chuck portion to the one side in the first direction and the chuck portion to perform an opening operation along with movement of the chuck portion to the other side in the first direction.
   (3)

The transport robot according to (2) above, in which the first hand includes a first hand main body to support the chuck mechanism, and
the opening and closing mechanism includes a cam mechanism including a cam pin arranged on one of the first hand main body and the chuck portion, and a cam groove provided on the other of the first hand main body and the chuck portion.
   (4)

The transport robot according to (2) above, in which the first hand includes a first hand main body to support the chuck mechanism,
the chuck portion includes a spindle that is moved in the first direction by the movement mechanism, and a first chuck member and a second chuck member that are rotatably coupled to the spindle,
the opening and closing mechanism includes a cam mechanism including a first cam groove arranged in the first chuck member, a second cam groove arranged in the second chuck member, and a cam pin that moves inside the first cam groove and the second cam groove, the cam pin being arranged in the first hand main body, and
the first cam groove and the second cam groove extend in a direction inclined oppositely to the first direction.
   (5)

The transport robot according to (4) above, in which the first cam groove and the second cam groove include a first region at an end on the other side in the first direction and a second region on the one side toward the first direction relative to the first region, respectively, and
the first region has a larger inclination angle relative to the first direction than the second region.
   (6)

The transport robot according to (5) above, in which the first region has an increasing inclination angle relative to the first direction toward the other side in the first direction.

(7)

The transport robot according to any one of (1) to (6) above, in which the first hand includes a pair of first plates extending from both sides of the chuck mechanism toward the one side in the first direction, and the pair of first plates support the workpiece from below.

(8)

The transport robot according to any one of (1) to (7) above, including a second hand including a suction portion to suction a surface of the workpiece,
a second movement mechanism to move the second hand to a delivery position vertically overlapped with the retreating position, and
a lifting and lowering mechanism to lift and lower the second hand moved to the delivery position.
   (9)

The transport robot according to (8) above, in which the second movement mechanism is a second multi-joint arm to move the second hand within a horizontal plane, and
the lifting and lowering mechanism is provided at a distal end of the second multi-joint arm and lifts and lowers the second hand relative to the second multi-joint arm.

What is claimed is:

1. A transport robot, comprising:
a first hand including a chuck mechanism to clamp and hold an outer peripheral end portion of a workpiece; and
a first movement mechanism to move the first hand to an advancing position where the workpiece contained in a workpiece container can be held and to a retreating position farther from the workpiece container than the advancing position, wherein
when a direction connecting the retreating position and the advancing position is defined as a first direction, a direction from the retreating position toward the advancing position is defined as one side in the first direction, and a direction from the advancing position toward the retreating position is defined as the other side in the first direction,
the chuck mechanism includes a chuck portion being openable and closable vertically, and a movement mechanism to move the chuck portion in the first direction.

2. The transport robot according to claim 1, wherein the chuck mechanism includes an opening and closing mechanism to open and close the chuck portion, and
the opening and closing mechanism causes the chuck portion to perform a closing operation along with movement of the chuck portion to the one side in the first direction and the chuck portion to perform an opening operation along with movement of the chuck portion to the other side in the first direction.

3. The transport robot according to claim 2, wherein the first hand includes a first hand main body to support the chuck mechanism, and
the opening and closing mechanism includes a cam mechanism including a cam pin arranged on one of the first hand main body and the chuck portion, and a cam groove provided on the other of the first hand main body and the chuck portion.

4. The transport robot according to claim 2, wherein the first hand includes a first hand main body to support the chuck mechanism,
the chuck portion includes a spindle that is moved in the first direction by the movement mechanism, and a first chuck member and a second chuck member that are rotatably coupled to the spindle,
the opening and closing mechanism includes a cam mechanism including a first cam groove arranged in the first chuck member, a second cam groove arranged in the second chuck member, and a cam pin that moves inside the first cam groove and the second cam groove, the cam pin being arranged in the first hand main body, and
the first cam groove and the second cam groove extend in a direction inclined oppositely to the first direction.

5. The transport robot according to claim 4, wherein the first cam groove and the second cam groove include a first region at an end on the other side in the first direction and a second region on the one side toward the first direction relative to the first region, respectively, and
the first region has a larger inclination angle relative to the first direction than the second region.

6. The transport robot according to claim 5, wherein the first region has an increasing inclination angle relative to the first direction toward the other side in the first direction.

7. The transport robot according to claim 1, wherein the first hand includes a pair of first plates extending from both sides of the chuck mechanism toward the one side in the first direction, and supports the workpiece from below by the pair of first plates.

8. The transport robot according to claim 1, comprising:
a second hand including a suction portion to suction a surface of the workpiece;
a second movement mechanism to move the second hand to a delivery position vertically overlapped with the retreating position; and
a lifting and lowering mechanism to lift and lower the second hand moved to the delivery position.

9. The transport robot according to claim 8, wherein the second movement mechanism is a second multi-joint arm to move the second hand within a horizontal plane, and
the lifting and lowering mechanism is provided at a distal end of the second multi-joint arm and lifts and lowers the second hand relative to the second multi-joint arm.
